(19) United States
(12) Patent Application Publication
(10) Pub. No.: US 2021/0367391 A1
(43) Pub. Date: Nov. 25, 2021

(54) PUMP REFLECTORS FOR CLADDING-PUMPED OPTICAL FIBER SYSTEMS

(71) Applicant: UNIVERSITÉ LAVAL, Québec (CA)

(72) Inventors: Martin BERNIER, Québec (CA); Lauris TALBOT, Québec (CA)

(21) Appl. No.: 17/325,632

(22) Filed: May 20, 2021

Related U.S. Application Data
(60) Provisional application No. 63/027,617, filed on May 20, 2020.

(51) Int. Cl. H01S 3/067; H01S 3/094

(52) U.S. Cl. CPC H01S 3/06733; H01S 3/0675; H01S 3/094007

(57) ABSTRACT

Pump reflectors for use in cladding-pumped fiber systems, such as laser or amplifier systems, are provided. The pump reflector includes an optical fiber segment having at least one core and at least one cladding. A cladding Bragg grating is written by femtosecond inscription in the optical fiber segment, and extending across at least a portion of the cladding. The cladding Bragg grating has a reflectivity profile encompassing the spectral profile of the pump and a spatial profile encompassing the pump spatial distribution in the cladding. A method of manufacturing a pump reflector using femtosecond light pulses is also provided.

### TECHNICAL FIELD

The technical field generally relates to optical fiber systems such as fiber lasers and amplifiers, and more particularly concern a pump reflector for use in such systems and a method of manufacture thereof.

### BACKGROUND

The cladding-pumping scheme for fiber lasers has made their power scaling possible, thus opening their use for many high-end applications.

Referring to FIG. 1 (PRIOR ART), the configuration of a typical cladding-pumped fiber laser is schematically illustrated. The fiber laser includes a length of active fiber acting as a gain medium for the light amplification process. The active fiber is generally embodied by a rare-earth-doped silica fiber. The laser cavity is defined by a high-reflectivity fiber Bragg grating (HR-FBG) and a low-reflectivity fiber Bragg grating (LR-FBG) provided on either side of the gain medium. Typically, the HR-FBG and LR-FBG are inscribed in passive optical fibers spliced to either ends of the length of active fiber. A pump diode generates a pump beam injected into a large core optical fiber spliced to the passive fiber hosting the HR-FBG, so that the pump beam is coupled into numerous cladding modes and travels in the cladding of the fibers of the laser cavity.

This approach allows one to easily couple low brightness and highly multimode but very powerful pump light into the cladding of the active fiber. The pump light is then absorbed along the fiber and converted to a core-guided laser signal, with an excellent beam quality and therefore a very large brightness.

Cladding-pumping reduces the pump absorption rate compared to core-pumping schemes, distributing the gain along much longer lengths. This distribution of the pump absorption greatly facilitates the thermal dissipation of the heat generated during such a process. However, laser cavity lengths have to be particularly long to achieve substantial pump absorption. The laser cavity becomes consequently more lossy and expensive, and starts to be sensitive to nonlinear effects, since the fiber length at high power becomes comparable to the characteristic nonlinear length.

Different strategies have been investigated to improve the pump absorption in cladding-pumping schemes. Referring for example to S. Baek, S. Roh, Y. Jeong and B. Lee, IEEE Photon. Technol. Lett. 18, 700 (2006), a long-period grating (LPG) was used to couple the pump power injected in the cladding of the active fiber into the core of a 4-m Yb-doped fiber cavity, which led to an enhancement of pump absorption from 55% to 80%. The highest power achieved by this laser consequently increased by 55%, from 4.67 to 7.27 W for 20 W of injected power. The LPG was UV-written in a photosensitive hydrogen-loaded single-mode and double-clad fiber using the point-by-point technique. Other approaches aimed to use all-fiber double pass pumping. As reported in Y. Jeong, S. Baek, J. Nilsson and B. Lee, Electron. Lett. 42, 15 (2006), a pump reflector was created by giving a right-angled conical shape to a passive single-mode fiber end with an electrical arc. The total internal reflection occurring at the fiber end led to a reflectivity of 55% of the residual pump power. It increased the lasing efficiency with respect to the launched pump power from 30% to 38% resulting in an increase of the maximum laser output power from 2.1 to 2.7 W. This has, however, the drawback of preventing the use of fusion splices with a protective endcap at the fiber end, thus limiting the power scalability of such an approach.

In another attempt to increase the pump absorption in cladding-pumped lasers, a pump reflector made of an inner cladding Bragg grating (ICBG) was UV-written using the phase-mask inscription technique inside the hydrogen-loaded germanosilicate inner cladding of a triple-cladding specialty Yb-doped active fiber (S. Baek, D. B. Soh, Y. Jeong, J. K. Sahu, J. Nilsson and B. Lee, IEEE Photon. Technol. Letter 16, 407 (2004)). A reflectivity of 46% for the residual pump power was achieved at the pump wavelength of 916 nm by writing the ICBG over the 42-μm diameter first inner cladding of such specialty fiber. The laser slope efficiency was increased from 21% to 30% with respect to injected pump power, whereas the maximum laser power went from 257 to 370 mW. UV-inscribed Bragg components have, however, the downside of requiring materials with enhanced photosensitivity, which greatly limits the gain fiber design.

There remains a need for providing an improved pump absorption in cladding-pumped lasers that alleviates at least some of the drawbacks of the prior art.

### SUMMARY

In accordance with one aspect, there is provided a pump reflector for a cladding-pumped fiber system carrying a pump beam having a pump spectral profile. The pump reflector comprises an optical fiber segment having at least one core and a cladding and configured to guide a core beam in a core mode and the pump beam in one or more cladding modes. The pump beam has a pump spatial distribution in the one or more cladding modes. The pump reflector further comprises a cladding Bragg grating written by femtosecond inscription in the optical fiber segment and extending across at least a portion of the cladding. The cladding Bragg grating has a reflectivity profile encompassing the pump spectral profile and a spatial profile encompassing the pump spatial distribution.

In some implementations, the cladding Bragg grating further extends across the core of the optical fiber segment. Alternatively, the cladding Bragg grating extends only in the cladding of the optical fiber segment. In some implementations, the cladding Bragg grating covers an entire cross-section of the cladding.

In some implementations, the cladding is an inner cladding of a multiclad fiber structure.

In some implementations, the cladding of the optical fiber segment is non-photosensitized.

In some implementations, the cladding and the core of the optical fiber segment are non-photosensitized.

In some implementations, the core of the optical fiber segment is doped with rare-earth ions.

In some implementations, the pump reflector is a pump stabilizing reflector.

In accordance with another aspect, there is provided a cladding-pumped fiber system, comprising:
a length of active optical fiber defining an active gain region, the length of active optical fiber being configured to support propagation of at least one core beam in at least one core mode and a pump beam in one or more cladding modes, the pump beam having a pump spectral profile and a pump spatial distribution in the cladding modes;
a pump source configured to generate the pump beam and optically coupled to the length of active optical fiber to inject the pump beam into the cladding modes thereof upstream the active gain region; and
a pump reflector provided in an optical fiber segment downstream the gain region, the optical fiber segment having at least one core and a cladding, the pump reflector comprising a cladding Bragg grating written by femtosecond inscription in the optical fiber segment and extending across at least a portion of the cladding, the cladding Bragg grating having a reflectivity profile encompassing the pump spectral profile and a spatial profile encompassing the pump spatial distribution.

In some implementations, the system further comprises a pair of cavity reflectors disposed on opposite sides of the active gain region, thereby defining a laser cavity. The the pair of cavity reflectors comprise a high-reflectivity fiber Bragg grating disposed upstream the active gain region and a low-reflectivity fiber Bragg grating disposed downstream the gain region.

In some implementations, the cavity reflectors are provided in the length of active optical fiber, and the optical fiber segment of the pump reflector is a portion of the length of active optical fiber.

In some implementations, the optical fiber segment of the pump reflector is connected to the length of active optical fiber.

In some implementations, the laser cavity comprises an input optical fiber and an output optical fiber connected to respective ends of the length of active optical fiber and each hosting a respective one of the cavity reflectors.

In some implementations, the optical fiber segment of the pump reflector is a portion of the output optical fiber.

In some implementations, the optical fiber segment of the pump reflector is connected to the output optical fiber.

In some implementations, the cladding Bragg grating of the pump reflector further extends across the core of the optical fiber segment.

In some implementations, the cladding Bragg grating of the pump reflector covers an entire cross-section of the cladding.

In some implementations, the cladding Bragg grating extends only in the cladding of the optical fiber segment.

In some implementations, the cladding of the optical fiber segment of the pump reflector is an inner cladding of a multiclad fiber structure.

In some implementations, the cladding of the optical fiber segment of the pump reflector is non-photosensitized.

In some implementations, the cladding and the core of the optical fiber segment of the pump reflector are non-photosensitized.

In some implementations, the system further comprises a pump stabilizing reflector provided between the pump source and the active gain region, the pump stabilizing reflector comprising a low reflectivity cladding Bragg grating written by femtosecond inscription, the cladding Bragg grating having a reflectivity profile encompassing the pump spectral profile and a spatial profile encompassing the pump spatial distribution.

In some implementations, the cladding-pumped fiber system further comprises:
a counterpropagating pump source configured to generate a counterpropagating pump beam and optically coupled to the length of active optical fiber to inject the counterpropagating pump beam into the cladding modes thereof downstream the active gain region;
a counterpropagating pump reflector provided upstream the gain region, the counterpropagating pump reflector comprising a cladding Bragg grating written by femtosecond inscription, the cladding Bragg grating of the counterpropagating pump reflector having a reflectivity profile encompassing a pump spectral profile and a spatial profile encompassing a pump spatial distribution of the counterpropagating pump beam.

In accordance with another aspect, there is provided a cladding-pumped fiber system, comprising:
a length of active optical fiber defining an active gain region, the length of active optical fiber being configured to support propagation of at least one core beam in at least one core mode and a pump beam in one or more cladding modes, the pump beam having a pump spectral profile and a pump spatial distribution in the cladding modes;
a pump source configured to generate the pump beam and optically coupled to the length of active optical fiber to inject the pump beam into the cladding modes thereof upstream the active gain region; and
a pump stabilizing reflector provided in an optical fiber segment between the pump source and the length of active optical fiber, the optical fiber segment having a cladding, the pump stabilizing reflector comprising a low reflectivity cladding Bragg grating written by femtosecond inscription in the optical fiber segment and extending across at least a portion of the cladding, the low reflectivity cladding Bragg grating having a reflectivity profile encompassing the pump spectral profile and a spatial profile encompassing the pump spatial distribution.

In accordance with another aspect, there is provided a method for manufacturing a pump reflector for a cladding-pumped fiber system, comprising:
providing an optical fiber segment having at least one core and one cladding and configured to guide a core beam in a core mode and a pump beam, having a pump spectral profile and a pump spatial distribution, in one or more cladding modes; and
impinging a writing beam of femtosecond light pulses on a cladding region of the optical fiber segment, the writing beam defining a grating pattern providing a cladding Bragg grating in the optical fiber segment having a reflectivity profile encompassing the pump spectral profile and a spatial profile encompassing the pump spatial distribution.

In some implementations, the method comprises diffracting the writing beam though a phase mask to create said grating pattern.

In some implementations, the method further comprises a step of moving the writing beam over said cladding region.

In some implementations, the method further comprises inserting the optical fiber segment in a glass capillary.

In some implementations, the method further comprises inserting the optical fiber segment in a support of same refractive index.

Other featured and advantages will be better understood upon a reading of embodiments with reference to the appended drawings.

### BRIEF DESCRIPTION OF THE DRAWINGS

FIG. 1 (PRIOR ART) is a schematic representation of a cladding-pumped fiber laser configuration according to prior art.

FIG. 2A is a schematic representation of a cladding-pumped fiber laser system according to one implementation; FIG. 2B is a schematic representation of a cladding-pumped fiber amplifier system according to one implementation.

FIGS. 3A and 3B are schematized cross-sectional end and side views of a pump reflector according to one variant; FIGS. 3C and 3D are schematized cross-sectional end and side views of a pump reflector according to another variant.

FIGS. 4A and 4B are schematized representation of cladding-pumped fiber laser systems according to some implementations.

FIGS. 5A and 5B are schematized representation of cladding-pumped fiber laser systems according to some implementations.

FIG. 6 is a schematized representation of an optical setup to manufacture a pump reflector according to some implementations.

FIG. 7 is a detailed schematized representation of an optical setup to manufacture a pump reflector according to some implementations.

FIG. 8, is a graph of the pump diode spectrum at high power along with the transmission spectra of three different pump reflectors written with the same inscription parameters but with different phase-masks with chirp rates of 1.2, 2.5 and 4.9 nm/cm.

FIG. 9 is a graph of the pump diode spectrum at high power along with the transmission and reflectivity spectra of a cladding Bragg grating written in an Er-doped fiber laser cavity.

FIG. 10 is a phase-contrast microscope image of the cross section of a cladding Bragg grating written with the same inscription parameters as the one of FIG. 9. The angle of incidence of the writing beam is given by the direction of the arrow.

FIG. 11 is a graph of the laser output power of an Er-doped fiber laser as function of the injected pump power with and without the presence of a cladding Bragg grating.

FIG. 12 shows simulations of the influence of the cladding Bragg grating reflectivity on the slope efficiency with regards to the cavity length.

FIGS. 13 A and 13B are images taken with a phase-contrast microscope of cladding Bragg gratings written with the same inscription parameters and a 2D scanning of the piezoelectric actuators over a range of ˜60 μm×65 μm: a) without a capillary; b) with a capillary. Laser is incident from the left.

FIG. 14 is a detailed schematized representation of an optical setup to manufacture a pump reflector according to some implementations.

FIG. 15 is a schematized representation of the cross section of an uncoated fiber inserted inside a capillary during the cladding Bragg grating inscription process.

FIG. 16 is a plot of the transmission spectrum of a cladding Bragg grating inscribed in the pure silica cladding of a passive fiber along with the pump diode spectrum operated at high power.

FIG. 17 is a graph of the laser curves of the Er-doped fiber laser with respect to the launched pump power with and without a cladding Bragg grating.

FIG. 18 illustrates the slope efficiencies calculated with simulations of the same all-fiber laser architecture using a cladding Bragg grating written in a passive fiber segment for different cavity lengths and cladding Bragg grating reflectivity.

FIG. 19 is a graph of the spectral emission evolution of a typical 120 W wavelength-stabilized diode, for different values of output power.

FIGS. 20A and 20B are schematized representation of cladding-pumped fiber laser systems according to some implementations including a pump stabilizing reflector.

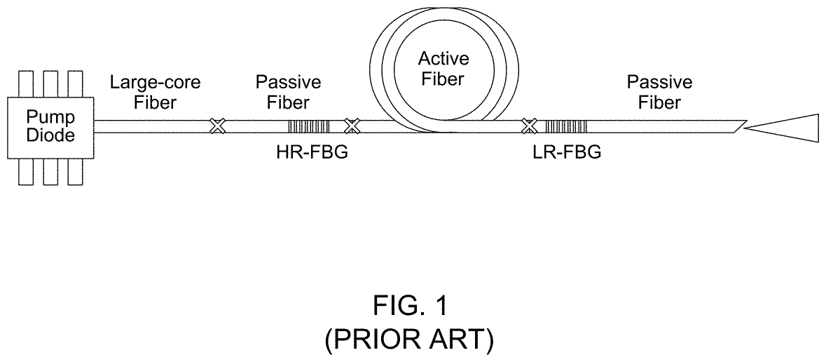

### DETAILED DESCRIPTION

The present description generally relates to pump reflectors and to their use in cladding-pumped fiber systems such as lasers and amplifiers. Methods and systems for manufacturing pump reflectors through the femtosecond inscription of Bragg gratings in a cladding region of an optical fiber are also presented.

In accordance with some implementations, femtosecond inscription is used to provide a cladding Bragg grating in an optical fiber segment of a cladding-pumped fiber system. In some implementations, the cladding Bragg grating may be used to reflect residual pump light back toward the active gain region of the fiber system, improving the pump absorption. In some implementations, the cladding Bragg grating may be designed and positioned to reflect a portion of the pump beam back into the pump source to stabilize its emission wavelength. Advantageously, femtosecond inscription enables the writing of the cladding Bragg grating in non-photosensitive optical fibers. More details on femtosecond inscription according to some embodiments are provided further below.

Throughout the present description, the expression “Bragg grating” is understood to refer to any periodic or aperiodic refractive index pattern permanently provided in an optical fiber. It will be understood by one skilled in the art that the Bragg grating may be single or multi-channel, and may be chirped, slanted, sampled, or involve more than one such characteristics. The Bragg grating has a reflectivity profile encompassing one or more target wavelengths, that is, the wavelength or wavelengths which require filtering by the Bragg grating in its predestined application. One skilled in the art will readily understand that the expression “target wavelength”, even used in the singular, is not meant to be limited to monochromatic light and may refer to a more complex spectral profile reflected or transmitted by the Bragg grating. In the description below, the expression “reflectivity profile”, applied to Bragg grating, is meant to refer to the variation of reflectivity as a function of wavelength of the grating.

In accordance with various aspects, pump reflectors such as described herein may enable and be used in a variety of fiber laser and amplifier configurations.

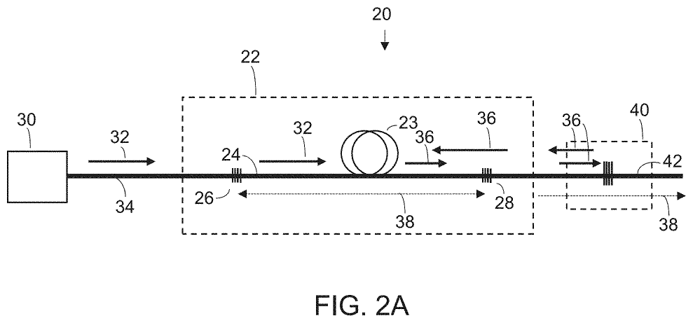

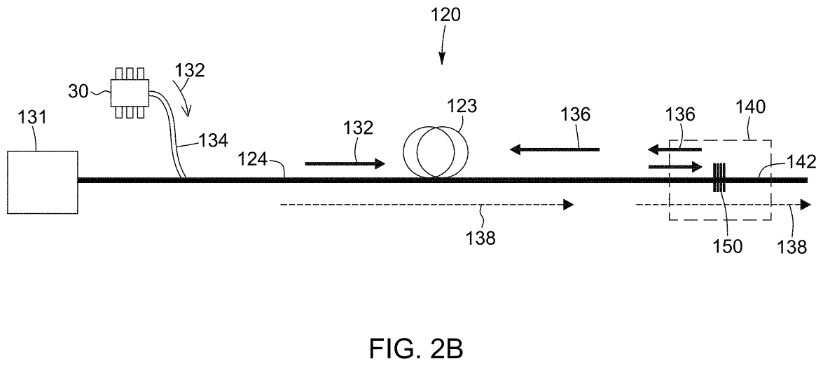

Referring to FIG. 2A, there is schematically illustrated a cladding-pumped fiber laser system 20 according to some implementations. The cladding-pumped fiber laser system includes a laser cavity 22, which, by definition, includes an active gain region 23 and a pair of cavity reflectors 26 and 28 disposed on opposite sides of this active gain region 23. Typically, the active gain region is defined by a length of active optical fiber 24 doped with at least one rare-earth dopant such as Erbium (Er), Ytterbium (Yb), Neodymium (Nd), Thulium (Tm) and the like. The cavity reflectors are typically embodied by a high-reflectivity fiber Bragg grating (HR-FBG) 26 and a low-reflectivity fiber Bragg grating (LR-FBG) 28.

The laser cavity 22 is configured to support propagation of a laser beam 38 generated and amplified in the active gain region 23. The laser beam 38 has a laser wavelength and typically propagates in a core mode of the active fiber 24, and is also referred to herein as a core beam. It will be readily understood that in some variants, the active fiber may have more than one core and/or support more than one core mode. As is known in the art, the laser beam 38 is amplified through multiple reflections between the cavity reflectors 26 and 28, and a portion of the laser beam 38 is allowed through the low-reflectivity fiber Bragg grating 28 and outputted by the fiber laser system 20.

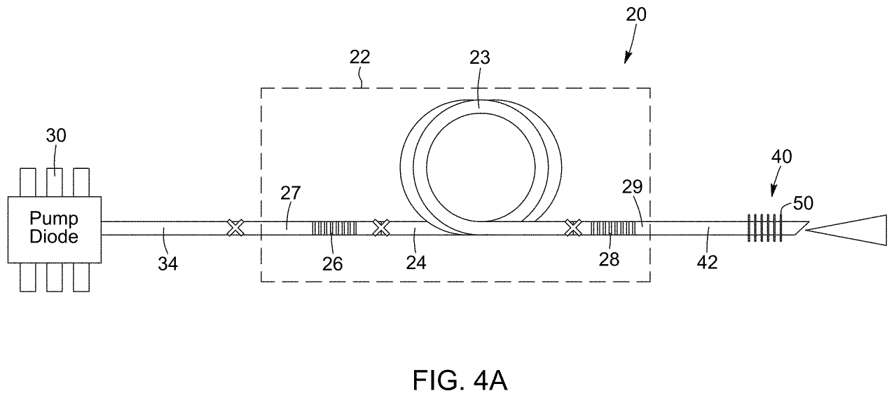

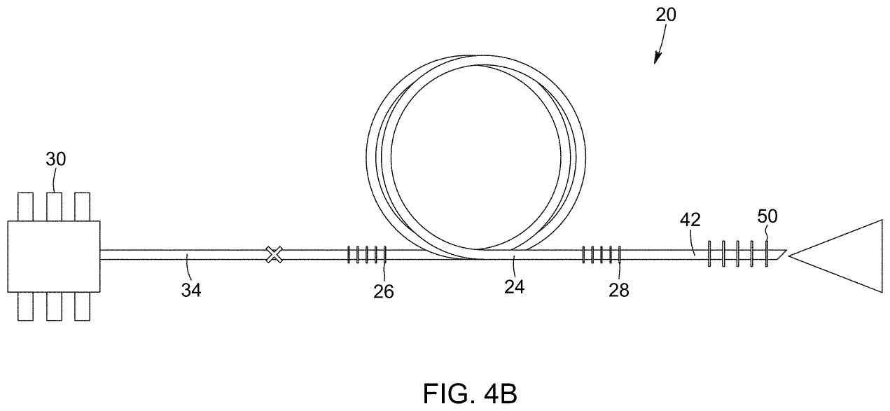

The cladding-pumped fiber laser system 20 further includes a pump source 30 configured to generate a pump beam 32. The pump beam 32 has a pump spectral profile and a pump spatial distribution. In some embodiments, the pump source 30 may be embodied by another fiber laser, an individual pump diode or by several pump diodes, encompassing single or multiple emitters, combined through the use of one or more pump combiners. The pump source 30 is optically coupled to the laser cavity 22 to inject the pump beam 32 into the cladding modes of the laser cavity 22, upstream the active gain region 23. In some embodiments (see FIGS. 4A and 4B), a large core optical fiber or a coreless optical fiber with only a cladding made of polymer 34 is optically coupled to the pump source 30 and spliced to the optical fiber segment hosting the HR-FBG 26. Other configurations, such as those based on free-space pump injection, may alternatively be envisioned.

As is known in the art, the pump beam 32 is partially absorbed by the active dopants of the active gain region 23 to create a population inversion leading to the generation and amplification of the laser beam 38. In typical implementations, however, the pump beam 30 may not be fully absorbed from a single pass along the active gain region 23, resulting in a residual portion 36 of the pump beam 32, also referred to as a residual pump 36, continuing beyond the active gain region 23. Advantageously, a pump reflector 40 as described herein may be provided in an optical fiber segment 42 downstream the active gain region 23 of the fiber laser cavity 22, to reflect the residual portion 36 of the pump beam back into the active gain region 23, therefore increasing the pump absorption.

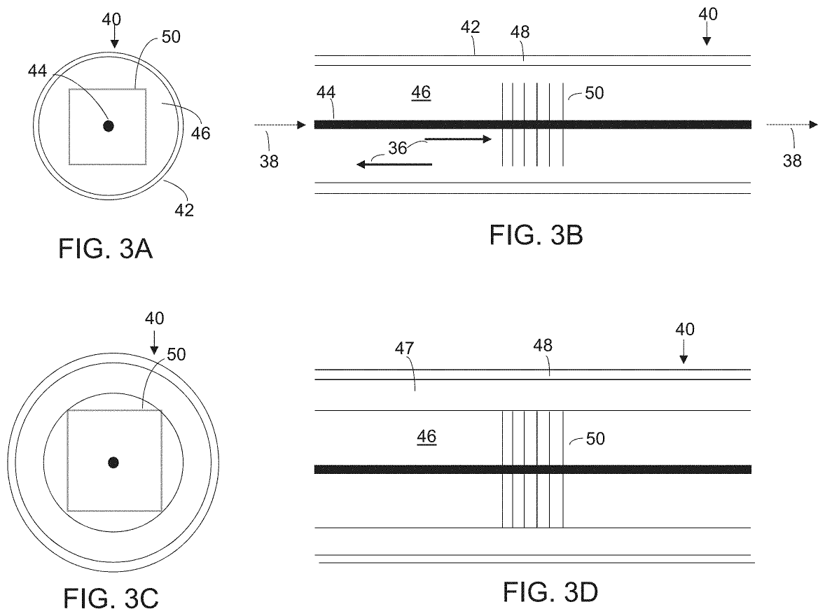

Referring to FIGS. 3A to 3D, pump reflectors 40 according to some implementations are schematically illustrated. The pump reflector 40 includes an optical fiber segment 42 having a core 44 and a cladding 46. In some embodiments, the optical fiber segment 42 may include more than one core and/or more than one cladding. The optical fiber segment may also include additional layers, such as a polymer coating 48, as well known in the art. The optical fiber segment 42 is configured to guide the core beam 38 in a core mode and to guide the residual pump beam 36 in one or more cladding modes, typically in several cladding modes. The pump reflector 40 further includes a cladding Bragg grating 50. The cladding Bragg grating 50 has a reflectivity profile encompassing the pump spectral profile and a spatial profile encompassing the pump spatial distribution in the cladding, as explained below. As also explained in further details below, the cladding Bragg grating 50 is written by femtosecond inscription in the optical fiber segment 42.

The cladding Bragg grating 50 extends across at least a portion of the cladding 46. It will be readily understood that the cladding Bragg grating 50 may also extend across the core 44 of the optical fiber segment 42, inasmuch as the reflectivity profile of the cladding Bragg grating does not encompass the wavelength of the core beam. However, in other variants, the cladding Bragg grating may extend only in regions of the cladding 46 of the optical fiber segment 42 to the exclusion of its core 44, for example defining a ring shape around the core. In other variants, the optical fiber segment 42 may have a non-concentric geometry, and may include a multicore and/or multicladding structure. By way of example, FIGS. 3C and 3D show a configuration wherein the cladding 46 bearing the cladding Bragg grating 50 is an inner cladding of a multiclad fiber structure, for example having an outer cladding 47 surrounding the inner cladding 46. In some embodiments the cladding Bragg grating 50 may cover only a portion of the cross-section of the cladding 46 (see FIGS. 3A and 3B), whereas in other variants it may cover an entire cross-section of the cladding 46 (see FIGS. 3C and 3D).

Advantageously, the cladding 46 and the core 44 of the optical fiber segment 42 may be non-photosensitized, which is generally understood by one skilled in the art as the absence of special pre-treatment of the fiber to enhance photosensitivity to UV radiation, such as germanium doping of and/or hydrogen loading. However, the pump reflector described herein may also be provided in optical fiber having been photosensitized. Further advantageously, in some embodiments the cladding Bragg grating may be provided directly in active optical fiber having a rare-earth core and/or cladding.

Referring to FIG. 2B, in some implementations the cladding-pumped fiber system may be embodied by an amplifier system 120. The amplifier system 120 includes a length of active optical fiber 124 defining an active gain region 123, the length of active optical fiber 124 being configured to support propagation of a core beam 138 for amplification in a core mode. The core beam 138 is seeded by a light beam from a seed laser 131 coupled to the active optical fiber 124. The length of active optical fiber 124 is further configured to support a pump beam 132 in several cladding modes, the pump beam 132 having a pump spectral profile. The cladding-pumped fiber amplifier system 120 further includes a pump source 130 configured to generate the pump beam 132 and optically coupled to the length of active optical fiber 124 to inject the pump beam 132 into the cladding modes thereof, upstream the active gain region 123. Finally, the cladding-pumped fiber amplifier system 120 includes a pump reflector 140 provided in an optical fiber segment 142 downstream the gain region 123. The pump reflector 140 may have a same or similar configuration as shown in FIGS. 3A to 3D, or equivalents thereto. As such the optical fiber segment 142 has at least one core and at least one cladding and includes a cladding Bragg grating 150 written by femtosecond inscription in the optical fiber segment 142 and extending across at least a portion of the cladding. The cladding Bragg grating 150 has a reflectivity profile encompassing the pump spectral profile and a spatial profile encompassing the pump spatial distribution in the cladding.

Referring to FIGS. 4A and 4B, more detailed examples of configurations of the cladding-pumped fiber laser system 20 are shown.

Referring to FIG. 4A, in the illustrated variant the laser cavity 22 includes an input optical fiber 27, hosting the high-reflectivity fiber Bragg grating 26, and an output optical fiber 29, hosting the low-reflectivity fiber Bragg grating 28. The input and output optical fibers 27 and 29 can be passive fibers, and are typically spliced (as indicated by an “X” in the figures) or otherwise connected to respective ends of the length of active optical fiber 24. In this variant the optical fiber segment 42 of the pump reflector 40 is a portion of the output optical fiber 29.

Referring to FIG. 4B, in other implementations the cavity reflectors 26 and 28 may be inscribed in the length of active optical fiber 24 itself. Advantageously, in this variant the optical fiber segment 42 hosting the pump reflector 40 may be a portion of the active optical fiber 24. In other words, the cladding Bragg grating 50 is inscribed directly in the active optical fiber 24.

It will be readily understood that other variants may be envisioned. By way of example, in alternative embodiments (not shown), the optical fiber segment of the pump reflector may be embodied by another piece of optical fiber spliced to the output optical fiber. Furthermore, although the illustrated variants shown the pump reflector outside of the laser cavity, In some implementations (not shown) the pump reflector may be positioned inside the laser cavity, for example between the active gain region and the low-reflectivity fiber Bragg grating.

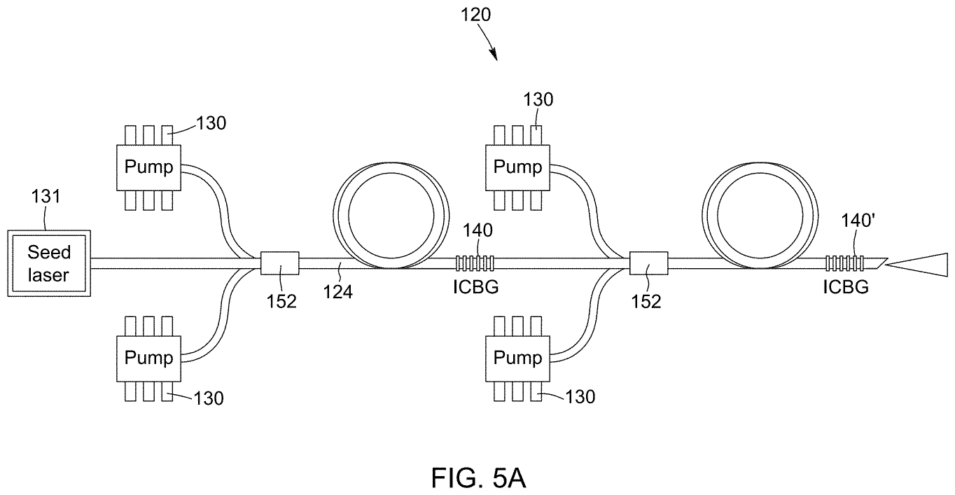

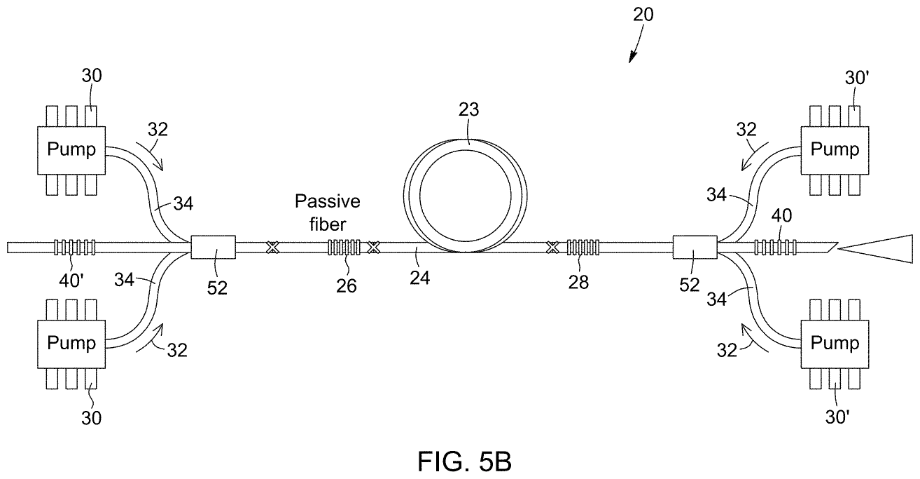

Referring to FIGS. 5A and 5B, in some implementations, cladding-pumped fiber systems including multiple pump sources and/or multiple pump reflectors may be envisioned. By way of example, in FIG. 5A, there is shown a cladding-pumped fiber system 120 including a seed laser 131 and multiple pump sources 130 shown couple at different region of the length of active optical fiber 124, and an additional pump reflector 140′ similar to the pump reflector 140 may be distributed along the active gain segment. The multiple pump sources 130 may be interleaved between the pump reflectors 140, 140′ and side-coupled to the cladding of the active fiber 124 through pump combiners 52.

Referring to FIG. 5B, in yet another implementation the cladding-pumped fiber laser system 20 may include one or more counterpropagating pump sources 30′ each configured to generate a counterpropagating pump beam 32′. Each counterpropagating pump source 30′ is optically coupled to the length of active optical fiber 24 to inject the counterpropagating pump beams 32′ into the cladding modes thereof, downstream the active gain region 23. It will be understood that the expressions upstream and downstream are used herein with reference to light propagating towards the output of the cladding-pumped laser system, and that the reference to counterpropagation therefore designates light propagating in a direction opposite to the light output. A counterpropagating pump reflector 40′ is provided upstream the gain region 23, that is, on the input side of the laser cavity, for example before or after the high-reflectivity fiber Bragg grating 26 and before a side-coupled pump combiner 52. The counterpropagating pump reflector 40′ includes a cladding Bragg grating written by femtosecond inscription. The cladding Bragg grating of the counterpropagating pump reflector 40′ has a reflectivity profile encompassing a pump spectral profile and a spatial profile encompassing a pump spatial distribution of the counterpropagating pump beam 32′, and may have characteristics similar to those of the pump reflector 40 as described above. In this variant, the counterpropagating pump reflector 40′ may advantageously reflect unabsorbed residual pump light for yet another pass through the active gain region 23, providing further improvements in pump absorption.

In accordance with another aspect, there is provided a method for manufacturing a pump reflector for a cladding-pumped fiber system, such as lasers or amplifiers.

The method first involves providing an optical fiber segment having at least one core and at least one cladding. Optical fibers are typically composed of a light guiding core and one or more claddings surrounding the core. A protective polymer coating surrounds the outermost cladding. The core and cladding of the optical fiber segment may be made of glass such as silica or any type of oxide glass, and may be made of pure glass or may be doped with one or more dopants. Advantageously, the optical fiber segment, and in particular the cladding need not be made of a photosensitive material or be photosensitized prior to the writing of a Bragg grating therein. As such, co-doping any portion of the fiber with germanium, as is known in the art to enhance photosensitivity, is not required, although in some embodiments the core and/or cladding of the fiber may be germanium-doped and hydrogen- or deuterium-loaded to enhanced photosensitivity without departing from the scope of the invention.

In some embodiments, the optical fiber may alternatively be made of a crystalline material such as a sapphire, germanium, zinc selenide, yttrium aluminium garnet (YAG) or other crystalline materials with similar physical properties.

In other embodiments, the optical fiber may alternatively be made of low phonon energy glass such as a fluoride, chalcogenide or chalcohalide glass or other glass materials with similar physical properties. The low phonon energy glass medium can be of a variety of compositions, such as, but not limited to, doped or undoped fluoride glasses such as ZBLA, ZBLAN, ZBLALi, chalcogenide glasses such as As₂S₃ or As₂Se₃ or chalcohalide glasses. It is to be noted that low phonon energy glasses typically have physical properties that significantly differ from those of fused silica, including but not limited to a much higher thermal expansion coefficient, a much lower glass transition temperature and a lower thermal conductivity. Appropriate strategies may be used to take such properties under consideration, such as for example explained in U.S. Pat. No. 8,078,023 (VALLÉE et al.), the entire contents of which are incorporated herein by reference.

In some embodiments, the core and/or the cladding of the optical fiber can be doped with one or more rare-earth element such as ytterbium erbium, holmium, thulium, praseodymium, neodymium, dysprosium, etc, or combinations thereof. The optical fiber may also include other dopants such as aluminum, phosphorus, etc.

The method further includes impinging a writing beam of femtosecond light pulses on a cladding region of the optical fiber segment. As will be readily understood by one skilled in the art, femtosecond inscription refers to the local modification of the refractive index of a glass medium through non-resonant process multiphoton absorption of ultrafast light pulses. Femtosecond writing of Bragg structures is known to enable writing highly stable and strong fiber Bragg gratings directly in pure silica and other non-photosensitive materials. Advantageously, this approach does not require prior photosensitization of the medium, unlike prior art UV writing techniques which typically requires germanium doping and/or hydrogen loading.

The duration of the optical pulses is in the femtosecond range, preferably between 1 femtosecond and 2 picoseconds, and more preferably between 10 and 500 femtoseconds. The repetition rate of these optical pulses may for example be set between 1 Hz and 20 MHz. As one skilled in the art will readily understand, at low repetition rate, for example less than 1 Hz, the writing process requires a longer exposure time to reach a target reflectivity of the Bragg grating, which may lead to mechanical instabilities and therefore limit the growth of the grating. The use of a high repetition rate (i.e. above 250 kHz) enables a shorter exposure time to reach the same target reflectivity but may also lead to a local detrimental heating effect that would limit the grating growth. The repetition rate of the optical pulses is therefore preferably set to an appropriate value within the range above in order to avoid the detrimental effects of both extremes. To alleviate such detrimental heating effects and thus operate at higher repetition rates, a fast 2D or 3D scanner can be used to spread the beam spatially at high speed to distribute the heat load and make the writing process faster. It will, however, be understood that this range is given by way of information only and that different implementations may involve different repetition rates without departing from the scope of the invention.

The selection of the writing wavelength of the optical pulses, that is, their wavelength when they reach the fiber, preferably takes under consideration the optical properties of the optical fiber. The writing wavelength should be suitable to affect the cladding of the optical fiber segment in order to write the grating therein. It is known in the art that femtosecond light pulses in a glass material can lead to a permanent refractive index change in the material through one or more physical phenomena such as glass densification, the formation of color centers, the formation of damaged micro-structures, etc. It will be readily understood that one or more of these phenomena may be present in various embodiments of the method described herein without departing from the scope of the present invention. Femtosecond-inscribed Bragg components are usually obtained by using titanium-sapphire solid-state lasers or ytterbium-doped ultrafast fiber lasers emitting respectively ultrafast pulses at a wavelength ranging from 600 to 1200 nm. Furthermore, the light of such lasers is sometimes frequency doubled or even frequency tripled through non-linear processes for the needs of certain inscription applications. This gives to the writing beams a wavelength that can range from about 200 to 600 nm.

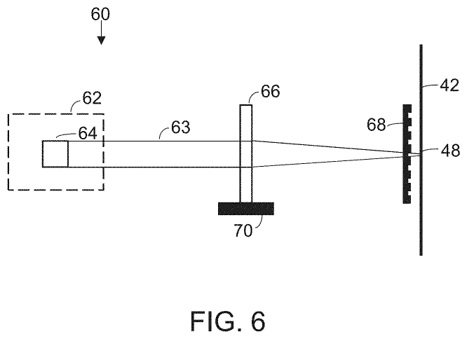

One skilled in the art will also readily understand that cladding Bragg gratings can be written using a variety of experimental set-ups or systems. Referring to FIG. 6, there is shown an example of an optical system 60 which may be used to perform the method according to some implementations.

The optical system 60 includes a light generator 62 configured to generate the writing light beam 63 of femtosecond optical pulses, as defined above. The light generator 62 may be embodied by or include a femtosecond laser source 64. Of course, the light generator 62 may include additional optical components such as mirrors, lenses and the like.

Still referring to FIG. 6, the optical system 60 further includes a phase mask 68, disposed between the light generator 62 and the optical fiber segment 42. It will be readily understood that the expression “phase mask” refers to a surface-relief structure forming corrugations in a material transmitting radiation at the writing wavelength. The corrugations define a diffraction grating having parameters selected such that the femtosecond pulses are diffracted by the phase mask to form the interference pattern defining the Bragg grating within the cladding region of the optical fiber segment 42. The phase mask 68 may for example be made of silica and may be fabricated according to any appropriate technique as well known in the art.

The phase mask 68 is characterised by a pitch corresponding to the period of its corrugations. The pitch of the phase mask 68 is selected according to the target wavelength of the cladding Bragg grating. To obtain a Bragg resonance at a design target wavelength □_{B}, the periodic modulation of the effective refractive index in the cladding region of the optical fiber segment must respect the phase-matching condition given by:

$$\frac{2 \cdot n \cdot π}{Λ} = 2 \cdot \frac{2 π \cdot {n}_{e f f}}{{λ}_{B}} \qquad ( 1 )$$

where n_{eff} is the effective refractive index of the medium of the cladding region, □ is the period of the interference pattern at the cladding region and n=1, 2, 3 . . . is the diffraction order. By simplification, we obtain:

$${λ}_{B} = 2 \cdot {n}_{e f f} \cdot \frac{Λ}{n} \qquad ( 2 )$$

The design wavelength □_{B} corresponds to the fundamental Bragg resonance for n=1. In some embodiments, the phase mask has a pitch providing the fundamental Bragg resonance as the target wavelength. Advantageously, such embodiments provide an optimal diffraction efficiency, that is, the grating coupling coefficient, (and therefore its reflectivity) is maximal for a given refractive index modulation. In other embodiments, the pitch of the phase mask may be selected to provide a high order resonance (n=2, 3, . . . ) at the target wavelength of the cladding Bragg grating.

The interference pattern obtained through diffraction of the femtosecond pulses by the phase mask and impinged on the cladding region of the optical fiber segment results in a modification of the refractive index of the glass in a permanent fashion, as explained above, therefore providing the desired Bragg grating. Preferably, the optical pulses are focussed on a region of the cladding surrounding the fiber core, in order to partially or totally cover the cladding modes to be reflected. However, in some implementations the grating region of the fiber in which the Bragg grating is written can be any suitable portion of the cladding of the fiber, and optionally its core. In some implementations the methods and systems described herein may provide for the writing of a very localized grating, which can be precisely located within the fiber.

Still referring to FIG. 6, in some implementations, the optical system 60 may include focussing component 66 or focussing assembly provided in a path of the writing light beam 63 and focussing the writing beam 63 onto the cladding region 46 of the optical fiber segment 42. In the illustrated example, the focussing component 66 is embodied by an acylindrical lens, which may advantageously provide a very localized spot where the writing beam impinges the cladding region 46 of the optical fiber segment 42. In some implementations, the writing beam 63 may be scanned along the longitudinal axis of the optical fiber segment, for example by moving the focussing component 66 while the optical fiber segment 42 and the phase mask 68 are kept fixed in close proximity of each other. The optical system 60 may further include a translation assembly 70 configured to translate the focussing component 66 along at least one axis, and preferably along three orthogonal axes.

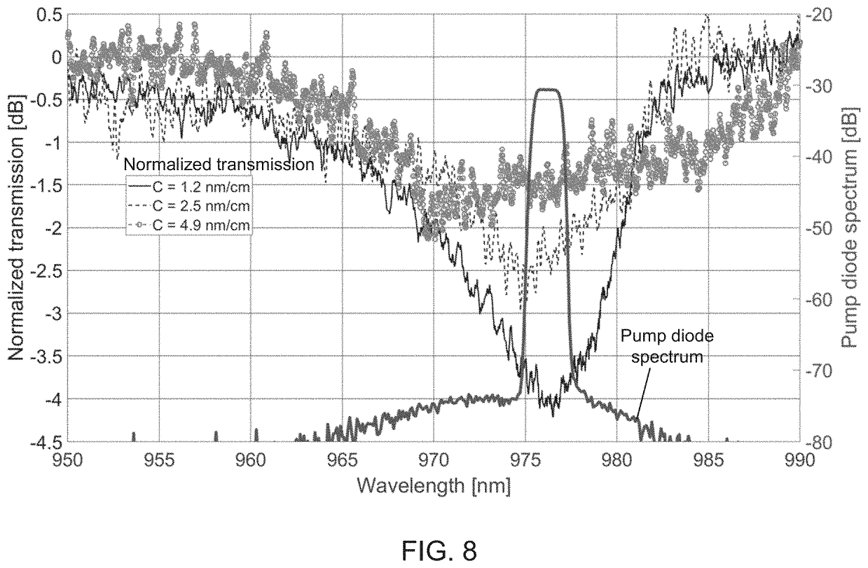

Referring to FIGS. 8 to 12, results from the manufacturing of a pump reflector according to one example of implementation are shown. The pump reflector was provided directly in an optical fiber segment of the length of active optical fiber of an all-fiber laser. The laser was made out of an in-house manufactured double-D shaped Er-doped silicate fiber having a core diameter of 17 μm and a NA of 0.061 with a pure-silica inner cladding with diameters of 120 μm×130 μm. The active fiber core was co-doped with erbium, aluminum, and phosphorus to help reduce the occurrence of clustering while maintaining a small numerical aperture to ensure single-mode operation. The fiber laser had a configuration similar to the one shown in FIG. 4B.

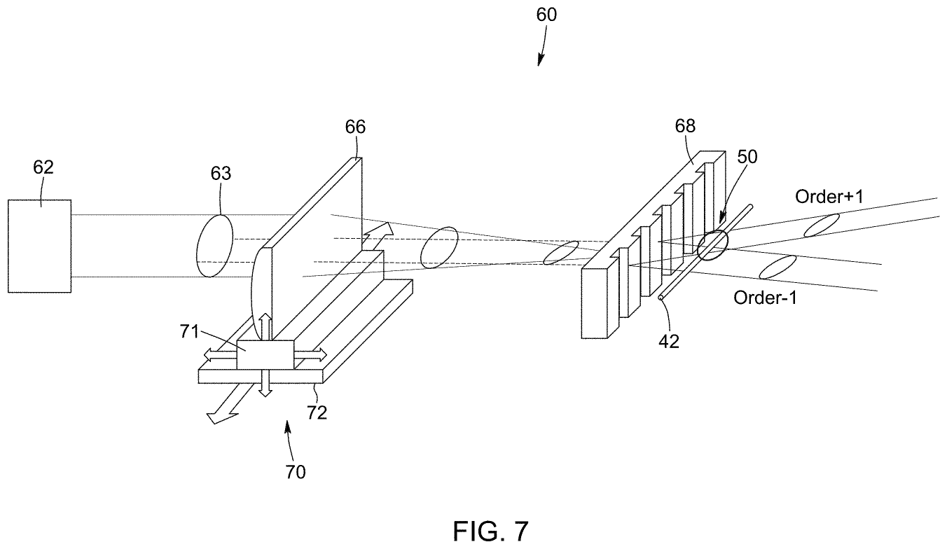

A cladding Bragg grating 50 was inscribed in the optical fiber segment 42 using an optical system 60 shown in FIG. 7, based upon the phase-mask technique and femtosecond laser exposure. The writing beam 63 was generated by a Ti-Sapphire regenerative amplifier system 62 (Astrella, Coherent Inc.) emitting 806 nm pulses at a repetition rate of 1 kHz with a maximum output energy of 6 mJ. The transform-limited pulse duration was about 30 fs as measured by using a single-shot autocorrelator. The beam was then sent through a BBO crystal (EKSMA optics, BBO 1502) to generate a second-harmonic signal at 403 nm made of ˜40 fs pulses with an energy that can reach 3 mJ. Both laser signals are separated by a dichroic mirror in order to send only the 403 nm beam towards the inscription setup. The writing beam 63 was focused by an acylindrical lens 66 with a short focal length of 10 mm, optimized for focusing with reduced aberration at 400 nm. The acylindrical lens 66 was fixed on a 2D-piezoelectric stage 71 that moved the writing beam 63 across a maximum range of ˜100 μm×100 μm, which corresponds to a conical-shaped writing area of ˜50 μm×50 μm in the optical fiber segment 42. The writing beam 63 was also scanned along the fiber axis with a translation stage 72 that moved the acylindrical lens 66 with respect to the optical fiber segment 42 and the phase mask 68 which are kept fixed in close proximity of each other. The interference pattern was created by in-house fabricated chirped phase masks 68 with a central pitch of 674 nm and various linear chirp rates. The decoated portion of the optical fiber segment 42 where the pump reflector was written was annealed at 475° C. for 10 min after inscription to eliminate the photoinduced absorption losses in the doped fiber core resulting from the intense laser exposure, which also stabilizes the cladding Bragg grating properties to expect a long-term stable operation.

The fiber laser was cladding-pumped by a fiber-coupled and wavelength-stabilized 976 nm diode (nLight, Element, e18) providing a maximum CW pump of 120 W. The wavelength of the pump beam was stabilized by an internal volume Bragg grating (VBG) which also considerably narrowed its emission spectrum. The diode pigtail was spliced to a 21 m laser cavity bounded by two FBGs directly written in the Er-doped fiber and inscribed through the coating, with the 800 nm beam described previously. The high reflectivity input coupler (HR-FBG) had a peak reflectivity of 99.9% over a broad bandwidth of 3 nm, while the output coupler (LR-FBG) had a 0.9% narrowband reflectivity to maximize the cavity performances. The optical fiber segment hosting the cladding Bragg grating was a portion of the active fiber positioned after the output coupler, near the laser output, and was decoated prior to inscription. After inscription and annealing, a low-index fluoroacrylate polymer is applied around the pump reflector to ensure efficient pump guiding and UV-cured in a V-grooved copper block to ensure an efficient conductive thermal dissipation. It should be noted that no active cooling systems are used. Finally, the fiber end at the laser output was cleaved at an angle of 4° to prevent parasitic lasing.

Before writing the cladding Bragg grating, optimization of the chirp rate for the phase-mask was conducted. The central wavelength and bandwidth of the pump reflector were matched to those of the pump diode. Since the pump propagation in the inner cladding of the Er-doped fiber is highly multimode (V˜185), the cladding Bragg grating is preferably chirped enough such that it can interact with most of the pump modes having different refractive indices. FIG. 8 shows the emission spectrum of the pump diode as well as the transmission spectrum of three cladding Bragg gratings written with the same nominal writing parameters, but with different chirp rates. They were all inscribed with 140 μJ pulses for a 25-min exposure time with a translation length of 26 mm along the mask and the fiber. They were then thermally annealed at 475° C. for 10 min. As expected, the width of the transmission peak is increased as the chirp rate increases, and the peak reflectivity decreases accordingly. The phase-mask with a chirp rate of 1.2 nm/cm was chosen as it resulted in a cladding Bragg grating that matched well the pump spectrum and offered the highest reflectivity. Further optimization could be done with reduced chirp rates and longer ICBGs in order to reach a stronger peak reflectivity.

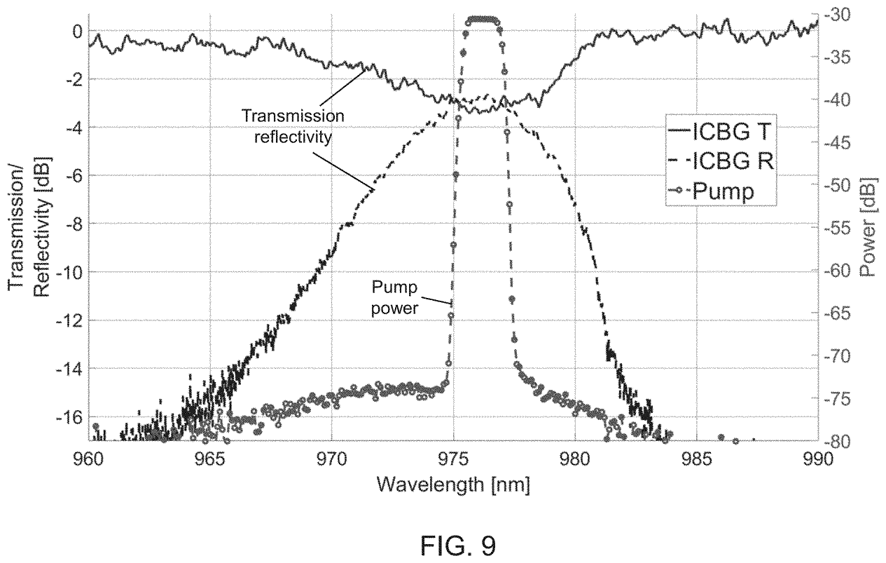

Once the phase-mask chirp rate was fixed at 1.2 nm/cm, the other writing parameters such as the pulse energy, the exposure time, and the grating length were optimized to reach the strongest pump reflectivity while not inducing significant core signal losses. The transmission spectrum of the final cladding Bragg grating used in the laser cavity before being recoated is shown on FIG. 9. It was written with 200 μJ pulses for 30 min and with a translation length of 26 mm. It was also thermally annealed at 475° C. for 10 min. An insertion loss of −3.2 dB was measured at 976 nm from which a peak reflectivity of about 53% can be inferred without measurable pump losses evaluated at wavelengths above the Bragg resonance. No significant signal losses (<0.1 dB limited by the measurement setup) near 1.6 μm could be measured by cutback.

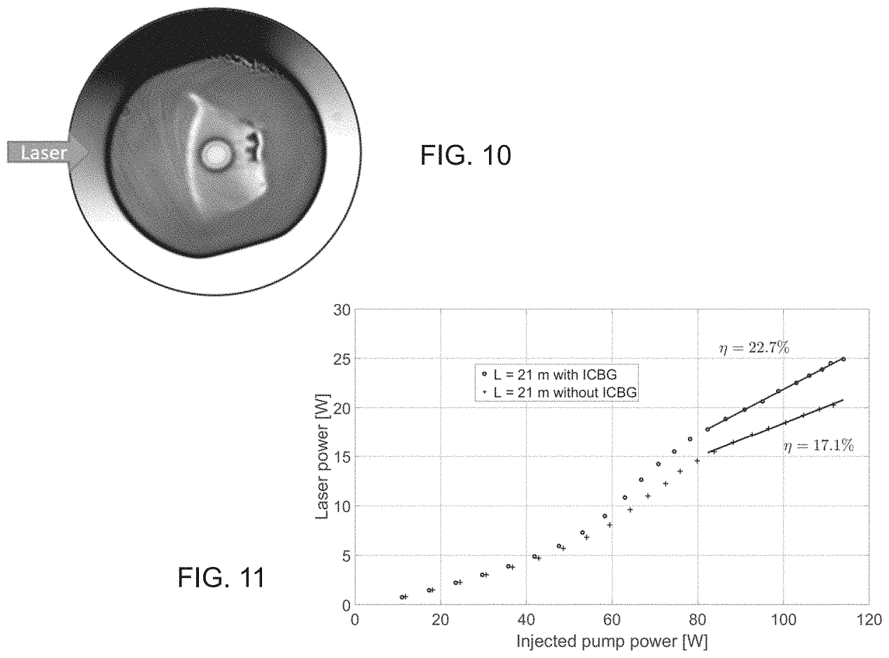

The influence of the curvature of the optical fiber segment on the shape of the writing surface can be seen on FIG. 10, where a fiber with cladding Bragg grating written under similar conditions as presented above was cleaved and analyzed with a phase-contrast microscope. As the beam is scanned during the inscription, it is refracted at different angles depending on its incident height on the optical fiber segment. This usually does not have a significant impact on the writing of FBGs since the core size is much smaller than the cladding curvature. However, for cladding-type Bragg gratings, it reduces the writing surface and distorts its shape into a conical profile

Hot spots where more energy was deposited during the writing can be seen FIG. 10 as black dots on the right side of the grating. No pump losses induced by those black spots were observed when they were written in the inner cladding as in that case. However, they could lead to important signal losses if they were overlapping the doped core region. Those hot spots are obtained if the beam is not exclusively incident on the curved part of the cladding during the scan. In fact, if the beam is scanned at the edge of the curved and straight surfaces of the optical fiber segment, hot spots will appear at the intersection of those two. The fiber orientation and alignment may therefore be of interest when a non-circular fiber is used. For the final pump reflector shown in FIG. 9, particular care was taken to properly align the fiber to prevent this effect from happening.

The performances of the laser cavity with and without the pump reflector are shown in FIG. 11. The curves have a nonlinear shape since the emission wavelength of the pump diode shifts as the power is increased. It changes from 962 nm at low power and gradually locks to 976 nm at output power around ˜80 W. The laser efficiencies are therefore only meaningful at high power when the pump spectrum matches the reflectivity spectrum of the cladding Bragg grating. One can see that the presence of the pump reflector significantly increased the cavity efficiency with respect to the launched pump power from 17.1% up to 22.7%, as well as the maximum output power from 20.8 to 25 W.

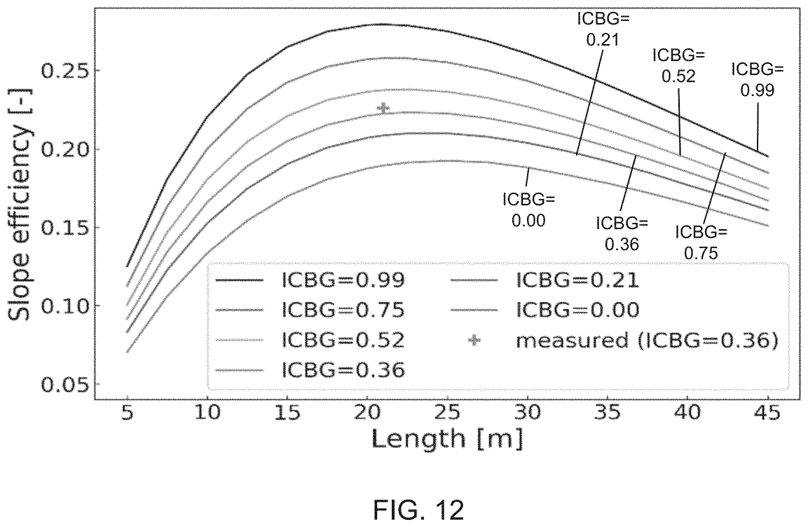

Numerical simulations of the laser cavity were performed using a similar model to the one presented in L. P. Pleau, P. Paradis, J.-S. Frenière, M. Huneault, S. Gouin, S. M. Aljamimi, Y. O. Aydin, S. Duval, J.-C. Gauthier, J. Habel, F. Jobin, F. Maes, L.-R. Robichaud, N. Grégoire, S. Morency and M. Bernier, Opt. Express 26, 22378 (2018), to evaluate the effective reflectivity of the cladding Bragg grating at high pump power and to study the influence of the reflectivity value on the laser performances. FIG. 12 shows the evolution of the expected laser slope efficiency for various cladding Bragg grating reflectivity as a function of the cavity length. The cross indicates the measured performances and indicates that the effective reflectivity would be about 36%, a value significantly lower than the 53% retrieved from the transmission measurement. This points out that the cladding Bragg grating does induce slight pump and/or signal losses that could be either absorbed and/or outcoupled from the fiber's numerical aperture to radiation modes. The simulations also show that with a 21 m meter cavity and a cladding Bragg grating with an effective reflectivity of 99%, the lasing efficiency could be increased up to 28% which confirms the great benefits of such a component for the laser performances. These calculations also indicate that the optimal cavity length without the cladding Bragg grating is 28 m. Adding an optimized cladding Bragg grating as a pump reflector reduces this optimal length to 21 m which allows for a direct reduction of the cavity length (cost) by 25%.

The transverse dimensions of the cladding Bragg grating, and thus its maximum reflectivity, may optionally be increased by using piezoelectric actuators with an enhanced range for the 2D-scanning of the acylindrical lens. The influence of the fiber's curvature on the refraction of the writing beam may then be limited by inserting the fiber into a hollow capillary with a much larger outside diameter or by using an active fiber with a larger inner cladding diameter. With the increased reflectivity of the ICBG, less energetic pulses could be used which would reduce the induced losses in the core. Another strategy to mitigate these limitations would be to write such a pump reflector in the passive fiber generally used as a delivery fiber which is undoped and of circular geometry.

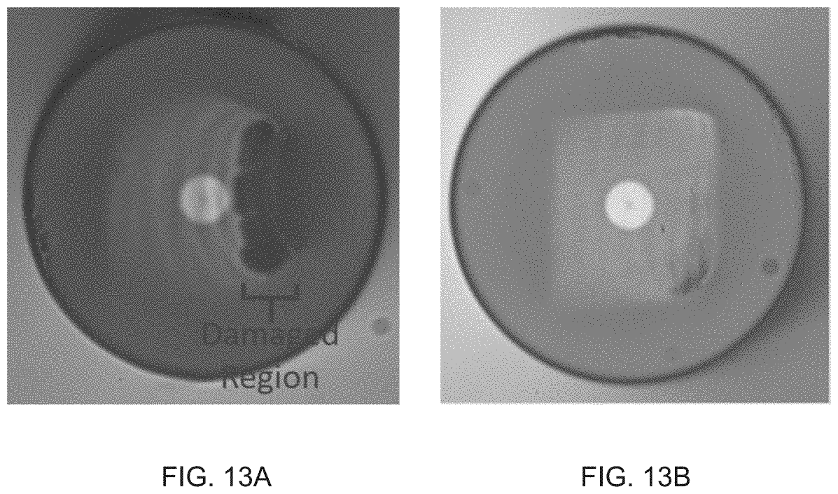

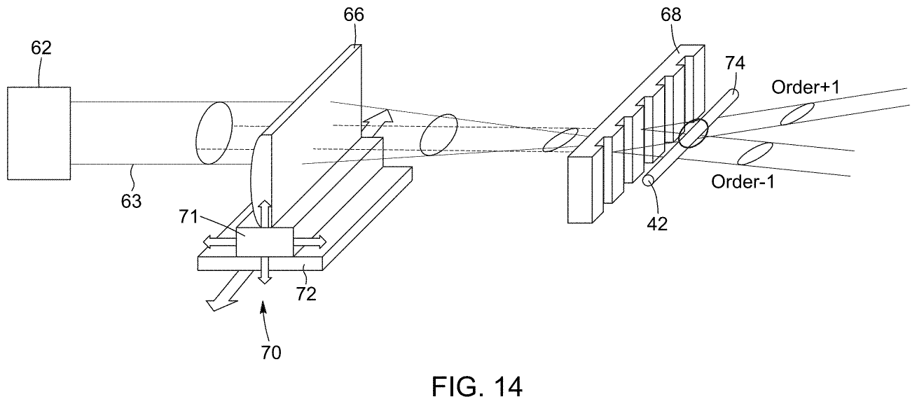

As discussed above, in some implementations the transverse area of the pump reflectors can be limited by the curvature of the optical fiber segment. FIG. 13A shows an example of how the fiber's curvature distorts the shape of the cladding Bragg grating. The refraction caused by the circular shape of the cladding can limit the maximum transverse area achievable for the pump reflectors. Furthermore, this creates hot spots on the opposite side of the grating from the incident side of the writing beam. Those regions where more energy is deposited can significantly hinder the power tolerability of the Bragg component since they tend to generate residual losses.

In accordance with some implementations, the method of manufacturing a pump reflector includes a step of inserting the optical fiber segment in a hollow capillary. Referring to FIG. 14, an example of an optical system that may be used to carry out the method in accordance with such embodiments is shown. In another set of experiments, pump reflectors were manufactured using such a system and similar writing parameters such as described above. The cladding Bragg gratings were written inside a passive silica fiber that is made of a GeO2-doped core with a diameter of 17 microns and a NA of 0.065. The inner cladding is made of pure silica and has a diameter of 125 μm. In this series, piezoelectric actuators with an enhanced scanning range compared to those used for the previously reported experiments were installed on the acylindrical lens mount.

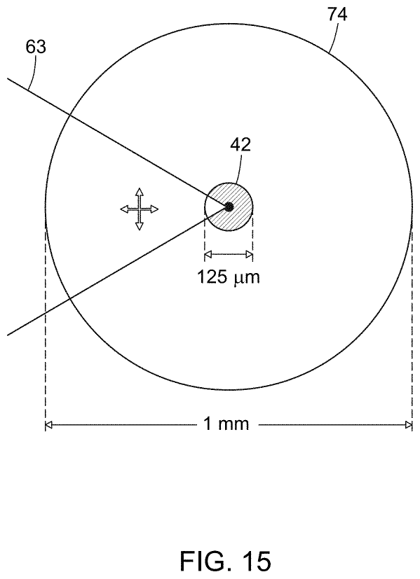

The system of FIG. 14 is similar to the one of FIG. 7, except that in this example, the optical fiber segment 42 was inserted inside a hollow capillary 74 made of pure silica glass. The capillary 74 had an inner diameter slightly larger than 125 μm and an outer diameter of 1 mm. The optical fiber segment 42 therefore fit snuggly within the cavity, such that its outer surface was close enough to the inner wall of the capillary to ensure continuous light propagation through the interface between them. The outer dimensions of the capillary 74 are selected to minimize refraction effects related to the angle of incidence of the writing beam on the air/glass interface, as best seen in FIG. 15. As seen on FIG. 13B, with the same scanning range as for the cladding Bragg grating seen on FIG. 13A, the scan surface is significantly less influenced by the much larger outer diameter of the capillary. It also avoids creating hot spots as the cladding Bragg grating cross section keeps a rectangular shape. It will be readily understood that in other implementations a U-shaped grooved thin silica substrate placed between the phase-mask and the fiber or other structures may be used instead of a capillary to obtain the same results. The spatial profile of the writing beam could also be managed passively or actively by using an adapted optical and/or optomechanical assembly in a way to ensure that most optical rays of the focused beam are incident perpendicular to the fiber surface. This would also ensure to minimize the effect of the fiber curvature on the writing beam profile.

The plump reflectors manufactured in this set of experiment were tested in a cladding-pumped fiber laser system configuration such as the one shown in FIG. 4A. The cavity reflectors and the cladding Bragg grating of the pump reflector were inscribed inside 125 μm-outer-diameter passive silica fibers of double-clad geometry with a GeO₂-doped core of 17 microns diameter and a core/clad NA of 0.065/0.46. The use of passive fibers spliced to the Er-doped gain fiber was motivated by the desire to power scale such a setup since Bragg components written directly inside Er-doped fibers used in previous experiment had some residual losses that may limit the output power scalability. The diode and the Er-doped fiber are the same as the one described above. The passive fiber was in-house manufactured while its NA and core diameter were chosen to ensure an optimal mode-size matching with the active fiber and a single-mode operation at the laser emission wavelength of 1.596 μm. The two FBGs that bound the 21 m long laser cavity were inscribed through the fiber coating with the 800 nm femtosecond beam and the phase-mask technique. The high reflectivity input coupler (HR-FBG) and the output coupler (LR-FBG) have respectively a reflectivity of 99.9% over a FWHM bandwidth of 3 nm and a reflectivity of 1% over a narrow FWHM bandwidth of 0.6 nm. Those parameters were chosen to achieve optimal performances at the laser wavelength of 1.596 μm. The cladding Bragg grating was written in the same segment of passive fiber than for the LR-FBG. It was written in an uncoated segment of the fiber. After the cladding Bragg grating inscription, the uncoated fiber segment was recoated with low index fluoroacrylate polymer to ensure efficient pump guiding in the inner cladding. The cladding Bragg grating was finally UV-cured in a V-grooved copper groove to passively cool it through conduction.

The output fiber end was cleaved at an angle of 6° to prevent parasitic feedback to the laser cavity. Both splices between the passive and the active fibers were carefully conducted and monitored to ensure a transmission greater than 98%.

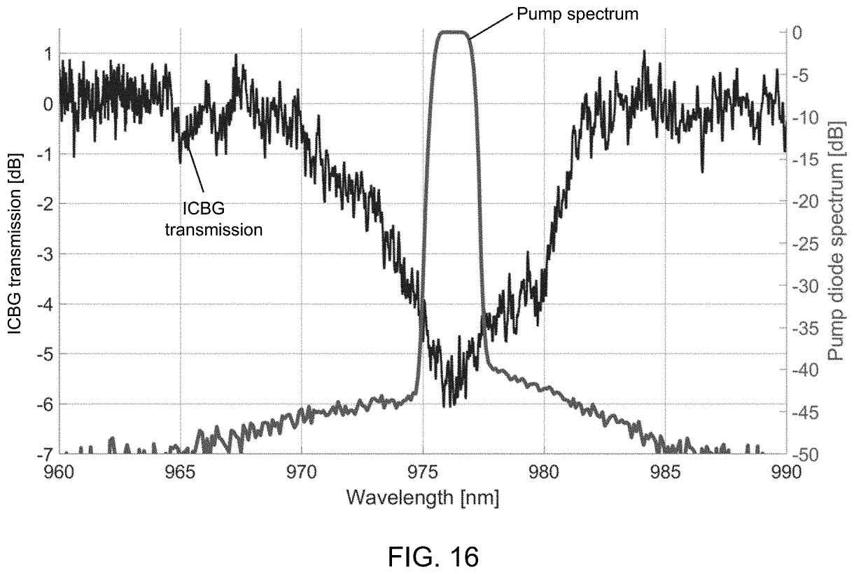

After optimizing the scanning range and the chirp for the writing of the cladding Bragg grating, the other inscription parameters were optimized. During that process, the transmission spectra of all cladding Bragg gratings were monitored in the same experimental conditions. A supercontinuum light source (NKT Photonics, Koheras) was injected inside a multimode silica fiber with a NA of 0.22 and a large core of 105 μm. It was then spliced to a segment of passive fiber in which the cladding Bragg grating was being written. After a thorough series of tests, a final cladding Bragg grating was inscribed with 185 μJ pulses during 45 minutes over a translation length of 26 mm. Its transmission spectrum recorded in the conditions described previously is shown on FIG. 16 along with the emission spectrum of the pump diode used for the laser driven at high power. The component has a peak reflectivity of 73%, inferred from its maximum insertion losses of −5.7 dB at 976 nm, and no measurable pump losses are observed. Several tests were conducted with the same inscription parameters in order to confirm the repeatability of this process with regards to the reflectivity performances of the cladding Bragg grating.

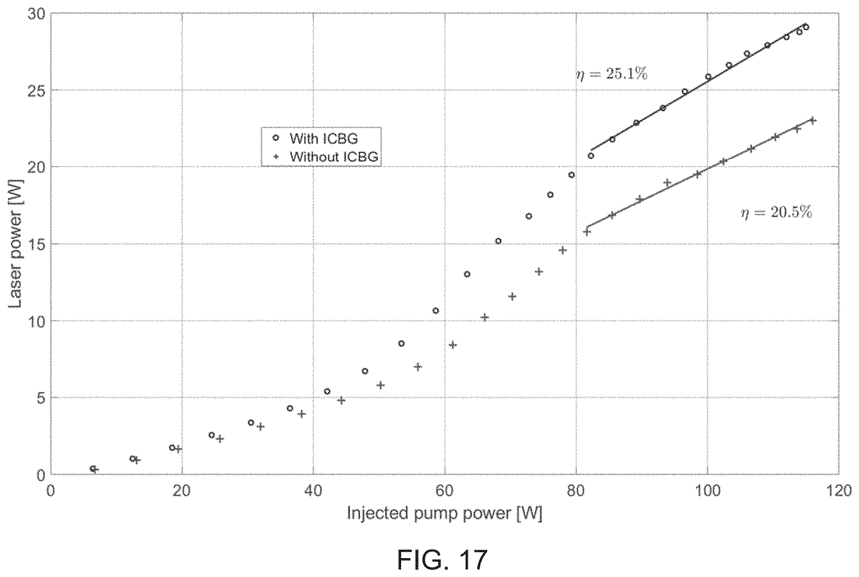

The impact of the pump reflector on the laser performances was then studied. Both laser curves with and without the cladding Bragg grating were measured with the same exact laser setup and are shown on FIG. 17. First of all, the laser curves are not linear at low power since the emission wavelength of the pump diode shifts with its operation power. It is wavelength stabilized with an internal VBG and its wavelength locks at 976 nm at high power around 80 W. At this point, the component increases the efficiency with regards to the launch pump power from 20.5 to 25.1%. It also increases the laser power from 22.8 to 29 W at a pump power of 115 W. Even though the cladding Bragg grating has a stronger reflectivity, the gain of efficiency is not greater than the one of the previous embodiments. This is due to the fact that the emission wavelength of the laser was changed from 1.584 to 1.596 μm and that the FBGs are no longer written directly in the active fiber, while the length of the cavity was kept to 21 m.

Simulations based on the same model used as above were conducted to evaluate the effective reflectivity of the cladding Bragg grating used in the laser setup. The obtained residual pump power and the laser output allowed to determine that the component reflected 58% of the unabsorbed pump power. This value is smaller than the 73% measured from its transmission spectrum through passive fiber because the cladding Bragg grating did not cover the whole cross section of the fiber. Therefore, its reflectivity changes depending on the transverse-modal distribution of the residual pump power. The core absorption of the active fiber tends to redistribute the modal content of the residual pump towards peripheral modes which have more power close to the outside diameter of the fiber. A longer Er-doped fiber therefore reduces the effective reflectivity of the cladding Bragg grating since it only covers the cladding region closer to the core. This discrepancy between the reflectivity measured in the two settings may be reduced by using strategies to cover the whole cross section of the inner cladding.

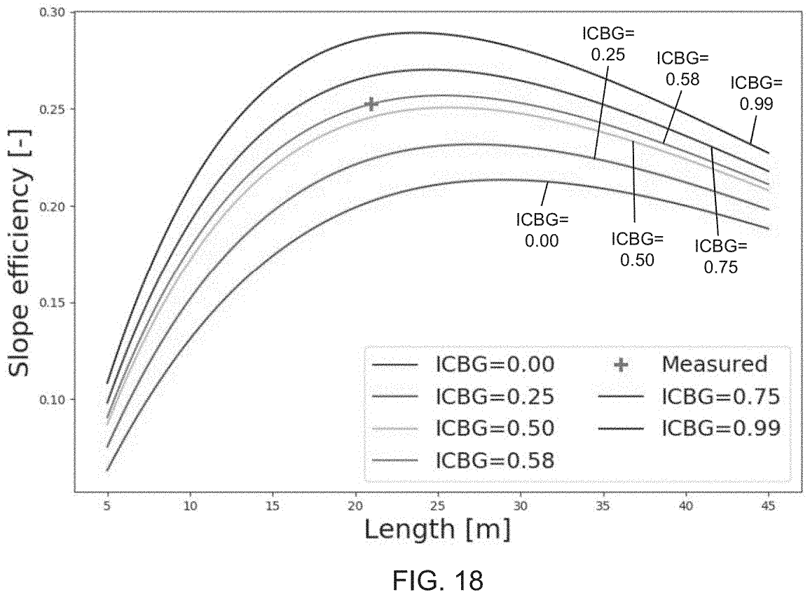

Those simulations were also used to evaluate the laser efficiency for different laser cavity lengths and for different cladding Bragg grating reflectivities. FIG. 18 shows that without a cladding Bragg grating, the optimum cavity length of 30 m will result in a maximum laser efficiency of 21.3%. With a cladding Bragg grating of 58% reflectivity, the same laser efficiency could be obtained with a cavity length of only 13 m, i.e. with a cavity length by a factor of more than two shorter. Furthermore, the maximum efficiency that could be reached with an optimized cladding Bragg grating having a reflectivity of 100% is 28.9%, i.e. a 35% increase of the maximum efficiency, for a cavity length of 23.7 m. This comparison points out the very beneficial impact of adding such pump reflector to a laser cavity.

In accordance with another aspect, pump reflectors such as described herein may alternatively or additionally be used as stabilizers for the pump source or sources.

Reflecting a portion of the pump beam back in the pump source of a laser or amplifier system can have the beneficial effect of stabilizing the emission wavelength of the pump source, such as for example diodes. Taken alone, diodes naturally emit light across a broad spectral width. Also, due to internal heating in such diodes, their peak wavelength shifts as their output power increases. Those two effects are known to reduce the efficiency of fiber lasers and amplifiers according to the injected pump power, as the rare earth ions dopant of the optically active fibers generally have spectrally narrow absorption cross sections. To circumvent this issue, it is known in the art to provide diodes commonly used to pump fiber systems with an internal wavelength stabilization element. The stabilization is usually achieved with a volume Bragg grating, that is, a bulk piece of glass with a Bragg structure inside, directly mounted into the pump module.

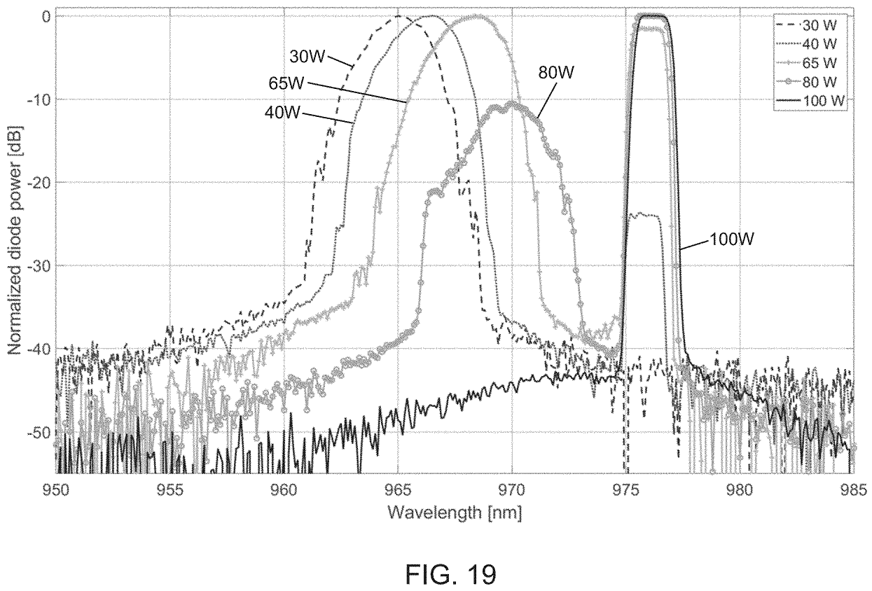

Referring to FIG. 19, there is shown the spectral emission evolution of a typical 120 W wavelength-stabilized diode, used alone. As can be observed, at an output power below 40 W, the diode naturally emits a broad peak around a wavelength of about 965 nm. Then, around 40 W, a second narrower peak at 976 nm starts appearing. This corresponds to the Bragg wavelength of the internal Volume Bragg grating of the diode. As the power is increased, the relative power of the 976 nm peak increases. Finally, beyond 80 W, the diode only emits the 976 nm peak. The impact of this behaviour on the output of a laser pumped by such a diode can be observed in the laser curves of FIG. 17. At low power, the efficiency or slope of the laser power with respect to the injected pump power is small. This is due to the fact that the peak wavelength of the pump diode is at 965 nm, for which the absorption cross section of erbium ions is smaller. As the pump power increases and the spectrum of the diode gradually locks to 976 nm, the efficiency continuously increases. Finally, above 80 W, the efficiency becomes constant since the diode wavelength is fully locked to 976 nm and does not shift. At this point, the diode's spectrum fully overlaps with the reflection spectrum of the inner cladding Bragg grating (ICBG) at the other end of the fiber laser shown on FIG. 16.

Even though both laser power curves of FIG. 17, with and without an ICBG, have the same shape, the presence of the pump reflector does have an additional impact on the spectrum of the diode used as pump source. According to FIG. 19, at pump powers below 40 W, there is negligible power in the 976 nm peak. The ICBG should therefore not be reflecting or interacting with the pump as its Bragg peak, seen in FIG. 16, does not cover the natural emission spectrum of the diode. However, according to FIG. 17, the laser with the ICBG still emits 19% more power than the laser without the pump reflector at 40 W (5 W vs. 4.2 W). This indicates that the pump reflector favours the stabilization of the pump wavelength at 976 nm at a lower output power. As the relative power in the 976 nm peak is enhanced, it increases the pump absorption and therefore the laser output power. The efficiency of the laser curve with an ICBG starts increasing at a lower amount of pump power than that of the laser without an ICBG. This clearly shows that the selective reflection of the residual pump power back towards the diode helps stabilizing its wavelength at 976 nm at a lower power. In the illustrated example, taking into account the effective reflectivity of this given ICBG and the pump absorption of the active fiber, it is evaluated that roughly 9% of the input power is reflected towards the large-core pigtail of the pump module when it is emitting at 976 nm. Taking into account the splice losses, this value is smaller than 9%.

This experiment reported above was conducted with a wavelength-stabilized diode. However, in some implementations, the provision of a pump reflector such as shown above to reflect a residual portion of the pump beam backwards in the system can have the additional beneficial effect of stabilizing the wavelength of the diode. Indeed, a fraction of the reflected residual pump beam may continue counterpropagating unabsorbed by the gain region, and be returned to the diode through the large-core fiber pigtail of the diode. This selective feedback at the pump reflector's Bragg wavelength forces the wavelength stabilization of the diode even if there is no internal stabilization element. The reflectivity of the cladding Bragg grating of the pump reflector and the length of the optically active fiber may be tailored to obtain a desired level of feedback in the diode, ensuring a robust wavelength stabilization even at low output power. Therefore, contrary to the design of typical diode manufactures using a feedback element inside the pump module, the proposed approach provides wavelength stabilizing feedback to the diode from the ICBG in the laser cavity. The configurations of FIGS. 4A and 4B may for example provide such a stabilization if the pump source 30 is non-stabilized and the characteristics of the pumps reflector 40 are selected accordingly.

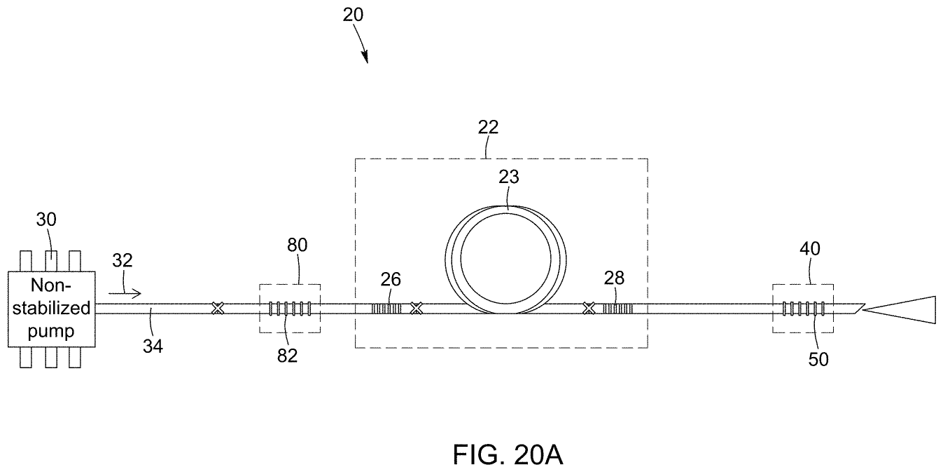

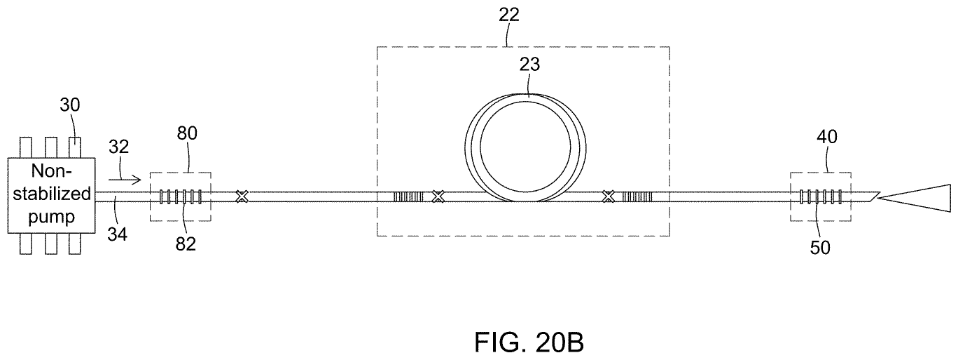

In some embodiments, referring for example to FIG. 20A, cladding-pumped fiber systems 20 such as described herein, or the like may additionally include a pump stabilizing reflector 80 provided between the pump source 30 and the active gain region 23. For example, in some implementations the selective feedback from the pump reflector 40 downstream the active gain region 23 may be insufficient to stabilize the diode as desired, due to a strong pump absorption of the active fiber. The provision of an additional pump stabilizing reflector 80 in the path of the pump beam 32 from the pump source 30 can provide sufficient additional feedback in the pump source 30 to obtain the desired wavelength stabilization. As seen in FIG. 20A, in one example the pump stabilizing reflector 80 includes a low reflectivity cladding Bragg grating 82 directly spliced to the large-core pigtail 34 of the pump source 30. The low reflectivity cladding Bragg grating 82 is written by femtosecond inscription, and has a reflectivity profile encompassing the pump spectral profile and a spatial profile encompassing the pump spatial distribution. The reflectivity of the low reflectivity cladding Bragg grating is preferably designed reflect enough pump power back in the pump source to assure the wavelength stabilization of the pump, while allowing through most of the power be injected in the cladding-pumped fiber system. Typically, the targeted reflectivity for such components is around 10-20%. In some embodiments, the reflectivity of the low reflectivity cladding Bragg grating may be specifically tailored to the diode used in the application, while not putting any constraints on the required active cavity length and the reflectivity of the cladding Bragg grating of the pump reflector downstream the active gain region.

Referring to FIG. 20B, in some implementations, the low reflectivity cladding Bragg grating 82 may be provided directly in the large core/coreless optical fiber 34 connected to the pump source 30. The multimode propagation properties of the pump beam inside the cladding of the laser cavity 22 are typically similar to the ones inside the large core/coreless optical fiber pigtail 34 of the diode, enabling such a configuration.

Of course, numerous modifications could be made to the embodiments described above without departing from the scope of protection.

1. A pump reflector for a cladding-pumped fiber system carrying a pump beam having a pump spectral profile, the pump reflector comprising:
an optical fiber segment having at least one core and a cladding and configured to guide a core beam in a core mode and the pump beam in one or more cladding modes, the pump beam having a pump spatial distribution in the one or more cladding modes; and
a cladding Bragg grating written by femtosecond inscription in the optical fiber segment and extending across at least a portion of the cladding, the cladding Bragg grating having a reflectivity profile encompassing the pump spectral profile and a spatial profile encompassing the pump spatial distribution.

2. The pump reflector according to claim 1, where the cladding Bragg grating further extends across the core of the optical fiber segment.

3. The pump reflector according to claim 1, wherein the cladding Bragg grating extends only in the cladding of the optical fiber segment.

4. The pump reflector according to claim 1, wherein the cladding Bragg grating covers an entire cross-section of the cladding.

5. The pump reflector according to claim 1, wherein the cladding is an inner cladding of a multiclad fiber structure.

6. The pump reflector according to claim 1, wherein the cladding of the optical fiber segment is non-photosensitized.

7. The pump reflector according to claim 1, wherein the cladding and the core of the optical fiber segment are non-photosensitized.

8. The pump reflector according to claim 1, wherein the core of the optical fiber segment is doped with rare-earth ions.

9. The pump reflector according to claim 1, wherein said pump reflector is a pump stabilizing reflector.

10. A cladding-pumped fiber system, comprising:
a length of active optical fiber defining an active gain region, the length of active optical fiber being configured to support propagation of at least one core beam in at least one core mode and a pump beam in one or more cladding modes, the pump beam having a pump spectral profile and a pump spatial distribution in the cladding modes;
a pump source configured to generate the pump beam and optically coupled to the length of active optical fiber to inject the pump beam into the cladding modes thereof upstream the active gain region; and
a pump reflector provided in an optical fiber segment downstream the gain region, the optical fiber segment having at least one core and a cladding, the pump reflector comprising a cladding Bragg grating written by femtosecond inscription in the optical fiber segment and extending across at least a portion of the cladding, the cladding Bragg grating having a reflectivity profile encompassing the pump spectral profile and a spatial profile encompassing the pump spatial distribution.

11. The cladding-pumped fiber system according to claim 10, further comprising:
a pair of cavity reflectors disposed on opposite sides of said active gain region, thereby defining a laser cavity.

12. The cladding-pumped system according to claim 11, wherein the pair of cavity reflectors comprise a high-reflectivity fiber Bragg grating disposed upstream the active gain region and a low-reflectivity fiber Bragg grating disposed downstream the gain region.

13. The cladding-pumped fiber system according to claim 11, wherein the cavity reflectors are provided in the length of active optical fiber, and the optical fiber segment of the pump reflector is a portion of the length of active optical fiber.

14. The cladding-pumped fiber system according to claim 10, wherein the optical fiber segment of the pump reflector is connected to the length of active optical fiber.

15. The cladding-pumped fiber system according to claim 11, wherein the laser cavity comprises an input optical fiber and an output optical fiber connected to respective ends of the length of active optical fiber and each hosting a respective one of the cavity reflectors.

16. The cladding-pumped fiber system according to claim 15, wherein the optical fiber segment of the pump reflector is a portion of the output optical fiber.

17. The cladding-pumped fiber system according to claim 15, wherein the optical fiber segment of the pump reflector is connected to the output optical fiber.

18. The cladding-pumped fiber system according to claim 10, wherein the cladding Bragg grating of the pump reflector further extends across the core of the optical fiber segment.

19. The cladding-pumped fiber system according to claim 10, wherein the cladding Bragg grating of the pump reflector covers an entire cross-section of the cladding.

20. The cladding-pumped fiber system according to claim 10, wherein the cladding Bragg grating extends only in the cladding of the optical fiber segment.

21. The cladding-pumped fiber system according to claim 10, wherein the cladding of the optical fiber segment of the pump reflector is an inner cladding of a multiclad fiber structure.

22. The cladding-pumped fiber system according to claim 10, wherein the cladding of the optical fiber segment of the pump reflector is non-photosensitized.

23. The cladding-pumped fiber system according to claim 10, wherein the cladding and the core of the optical fiber segment of the pump reflector are non-photosensitized.

24. The cladding-pumped fiber system of claim 10, further comprising a pump stabilizing reflector provided between the pump source and the active gain region, the pump stabilizing reflector comprising a low reflectivity cladding Bragg grating written by femtosecond inscription, the cladding Bragg grating having a reflectivity profile encompassing the pump spectral profile and a spatial profile encompassing the pump spatial distribution.

25. The cladding-pumped fiber system of claim 10, further comprising:
a counterpropagating pump source configured to generate a counterpropagating pump beam and optically coupled to the length of active optical fiber to inject the counterpropagating pump beam into the cladding modes thereof downstream the active gain region;
a counterpropagating pump reflector provided upstream the gain region, the counterpropagating pump reflector comprising a cladding Bragg grating written by femtosecond inscription, the cladding Bragg grating of the counterpropagating pump reflector having a reflectivity profile encompassing a pump spectral profile and a spatial profile encompassing a pump spatial distribution of the counterpropagating pump beam.

26. A cladding-pumped fiber system, comprising:
a length of active optical fiber defining an active gain region, the length of active optical fiber being configured to support propagation of at least one core beam in at least one core mode and a pump beam in one or more cladding modes, the pump beam having a pump spectral profile and a pump spatial distribution in the cladding modes;
a pump source configured to generate the pump beam and optically coupled to the length of active optical fiber to inject the pump beam into the cladding modes thereof upstream the active gain region; and
a pump stabilizing reflector provided in an optical fiber segment between the pump source and the length of active optical fiber, the optical fiber segment having a cladding, the pump stabilizing reflector comprising a low reflectivity cladding Bragg grating written by femtosecond inscription in the optical fiber segment and extending across at least a portion of the cladding, the low reflectivity cladding Bragg grating having a reflectivity profile encompassing the pump spectral profile and a spatial profile encompassing the pump spatial distribution.

27. A method for manufacturing a pump reflector for a cladding-pumped fiber system, comprising:
providing an optical fiber segment having at least one core and one cladding and configured to guide a core beam in a core mode and a pump beam, having a pump spectral profile and a pump spatial distribution, in one or more cladding modes; and
impinging a writing beam of femtosecond light pulses on a cladding region of the optical fiber segment, the writing beam defining a grating pattern providing a cladding Bragg grating in the optical fiber segment having a reflectivity profile encompassing the pump spectral profile and a spatial profile encompassing the pump spatial distribution.

28. The method according to claim 27, comprising diffracting the writing beam though a phase mask to create said grating pattern.

29. The method according to claim 27, further comprising a step of moving the writing beam over said cladding region.

30. The method according to claim 27, further comprising inserting the optical fiber segment in a glass capillary.

31. The method according to claim 27, further comprising inserting the optical fiber segment in a support of same refractive index.
